(19) United States
(12) Patent Application Publication
(10) Pub. No.: US 2019/0214503 A1
(43) Pub. Date: Jul. 11, 2019

(54) A P-TYPE THIN-FILM TRANSISTOR AND MANUFACTURING METHOD FOR THE SAME

(71) Applicant: SHENZHEN CHINA STAR OPTOELECTRONICS SEMICONDUCTOR DISPLAY TECHNOLOGY CO., LTD., Shenzhhen (CN)

(72) Inventors: MingJiue YU, Shenzhen (CN); YuanJun HSU, Shenzhen (CN)

(21) Appl. No.: 16/045,125

(22) Filed: Jul. 25, 2018

Related U.S. Application Data
(63) Continuation of application No. PCT/CN2018/078998, filed on Mar. 14, 2018.

(30) Foreign Application Priority Data
Jan. 8, 2018 (CN) 201810016577.X

(51) Int. Cl. H01L 29/786; H01L 29/417; H01L 29/423; H01L 29/66; H01L 23/532; H01L 21/02; H01L 21/48

(52) U.S. Cl. CPC H01L 29/78618; H01L 29/41733; H01L 29/42384; H01L 29/66742; H01L 27/3258; H01L 21/02304; H01L 21/02123; H01L 21/486; H01L 23/5329

(57) ABSTRACT

A P-type thin-film transistor and manufacturing method are provided. The method includes: forming an active layer having a P-type material on a buffering layer; forming a gate insulation layer on the active layer; depositing a gate metal layer on the gate insulation layer; forming a photoresist layer on the gate metal layer, and patterning the photoresist layer; etching the gate metal layer to form a gate electrode such that a projection of the gate electrode is within the patterned photoresist layer; using the patterned photoresist layer as a barrier layer to etch the gate insulation layer such that a projection of the gate electrode is within the gate insulation layer, and a projection of the gate insulation layer is within the active layer; doping two side regions of the active layer located below the gate insulation layer; and forming a source electrode and drain electrode on the doped regions.

### CROSS REFERENCE

This application is a continuing application of PCT Patent Application No. PCT/CN2018/078998, entitled “A P-type thin-film transistor and manufacturing method for the same”, filed on Mar. 14, 2018, which claims priority to China Patent Application No. CN201810016577.X filed on Jan. 8, 2018, both of which are hereby incorporated in its entireties by reference.

### FIELD OF THE INVENTION

The present invention relates to a semiconductor technology field, and more particularly to a P-type thin-film transistor and manufacturing method for the same.

### BACKGROUND OF THE INVENTION

In a conventional TFT-LCD panel, an active layer of a thin-film transistor generally adopts an N-type material (such as indium gallium zinc oxide, indium tin oxide). Therefore, in the TFT-LCD panel, the thin-film transistor adopting N-type is more. However, in an AMOLED (Active-matrix organic light emitting diode) panel, adopting P-type is more. Along with a requirement of increasing size of the display panel and high resolution, decreasing a parasitic capacitance of the p-type thin-film transistor and decreasing a leakage current of the P-type thin-film transistor is more helpful to realize a high resolution requirement of the AMOLED panel.

### SUMMARY OF THE INVENTION

In order to solve the above technology problem, the present invention provides a P-type thin-film transistor and a manufacturing method for P-type thin-film transistor, which can decrease the parasitic capacitance of the p-type thin-film transistor and decrease a leakage current of the P-type thin-film transistor.

The present invention provides a manufacturing method for P-type thin-film transistor, comprising steps of: forming an active layer having a P-type material on a buffering layer; forming a gate insulation layer on the active layer; depositing a gate metal layer on the gate insulation layer; forming a photoresist layer on the gate metal layer, and patterning the photoresist layer; etching the gate metal layer in order to form a gate electrode such that a projection of the gate electrode on the patterned photoresist layer is within the patterned photoresist layer; using the patterned photoresist layer as a barrier layer to etch the gate insulation layer such that a projection of the gate electrode on the gate insulation layer is within the gate insulation layer, and a projection of the gate insulation layer on the active layer is within the active layer; doping two side regions of the active layer located below the gate insulation layer after being etched; and forming a source electrode and a drain electrode on the doped regions of the active layer.

Preferably, the method further comprises steps of: forming an interlayer dielectric layer on the buffering layer, and the interlayer dielectric layer covers the gate electrode; forming two vias on the interlayer dielectric layer, and the two vias are located above the doped regions of the active layer; forming the source electrode and the drain electrode on the doped regions of the active layer, wherein forming the source electrode and the drain electrode on the interlayer dielectric layer, and the source electrode and the drain electrode are respectively connected with the doped regions of the active layer through the two vias.

Preferably, the method further comprises steps of: forming a passivation layer on the interlayer dielectric layer, and the passivation layer covers the source electrode and the drain electrode, wherein a range of a thickness of the passivation layer is 1000˜5000 angstrom, and the passivation layer includes at least one layer of SiOx and/or at least one layer of SiNx.

Preferably, a range of a thickness of the interlayer dielectric layer is 2000˜10000 angstrom, and the interlayer dielectric layer includes at least one layer of SiOx and/or at least one layer of SiNx.

Preferably, the method further includes steps of forming the buffering layer on a glass substrate; removing the photoresist layer after etching the gate metal layer to form the gate electrode and before doping the active layer, or removing the photoresist layer after doping the active layer; a range of a thickness of the buffering layer is 1000˜5000 angstrom; the buffering layer includes at least one layer of SiOx and/or at least one layer of SiNx.

Preferably, the method uses a wet etching method to etch the gate metal layer in order to form the gate electrode, and uses a dry etching method to etch the gate insulation layer, and uses a UV light to define a pattern of the photoresist layer.

Preferably, a range of a thickness of the active layer is 100˜1000 angstrom; a material of the active layer is a copper oxide material, and the copper oxide material is one or at least two of Cu2O, CuAlO2, LaCuOS; a range of a thickness of each of the source electrode and the drain electrode is 2000˜8000 angstrom; a range of a thickness of the gate insulation layer is 1000˜3000 angstrom; a material of each of the gate electrode, the source electrode and the drain electrode is one of Mo, Al, Cu, Ti, a molybdenum alloy, an aluminum alloy, a copper alloy, and a titanium alloy; the gate insulation layer includes at least one layer of SiOx and/or one layer of SiNx.

The present invention further provides a manufacturing method for P-type thin-film transistor, comprising steps of: forming an active layer having a P-type material on a buffering layer; forming a gate insulation layer on the active layer; depositing a gate metal layer on the gate insulation layer; forming a photoresist layer on the gate metal layer, and patterning the photoresist layer; etching the gate metal layer in order to form a gate electrode such that a projection of the gate electrode on the patterned photoresist layer is within the patterned photoresist layer; using the patterned photoresist layer as a barrier layer to etch the gate insulation layer such that such that a projection of the gate electrode on the gate insulation layer is within the gate insulation layer, and a projection of the gate insulation layer on the active layer is within the active layer; doping two side regions of the active layer located below the gate insulation layer after being etched; forming a source electrode and a drain electrode on the doped regions of the active layer; wherein the method for P-type transistor further includes steps of: forming the buffering layer on a glass substrate; removing the photoresist layer after etching the gate metal layer form the gate electrode and before doping the active layer, or removing the photoresist layer after doping the active layer; a range of a thickness of the buffering layer is 1000˜5000 angstrom; the buffering layer includes at least one layer of SiOx and/or at least one layer of SiNx.

Preferably, the method further comprises steps of: forming an interlayer dielectric layer on the buffering layer, and the interlayer dielectric layer covers the gate electrode; forming two vias on the interlayer dielectric layer, and the two vias are located above the doped regions of the active layer; forming the source electrode and the drain electrode on the doped regions of the active layer, wherein forming the source electrode and the drain electrode on the interlayer dielectric layer, and the source electrode and the drain electrode are respectively connected with the doped regions of the active layer through the two vias.

Preferably, the method further comprises steps of: forming a passivation layer on the interlayer dielectric layer, and the passivation layer covers the source electrode and the drain electrode, wherein a range of a thickness of the passivation layer is 1000˜5000 angstrom, and the passivation layer includes at least one layer of SiOx and/or at least one layer of SiNx.

Preferably, a range of a thickness of the interlayer dielectric layer is 2000˜10000 angstrom, and the interlayer dielectric layer includes at least one layer of SiOx and/or at least one layer of SiNx.

Preferably, the method uses a wet etching method to etch the gate metal layer in order to form the gate electrode, and uses a dry etching method to etch the gate insulation layer, and uses a UV light to define a pattern of the photoresist layer.

Preferably, a range of a thickness of the active layer 100˜1000 angstrom; a material of the active layer is a copper oxide material, and the copper oxide material is one or at least two of Cu2O, CuAlO2, LaCuOS; a range of a thickness of each of the source electrode and the drain electrode is 2000˜8000 angstrom; a range of a thickness of the gate insulation layer is 1000˜3000 angstrom; a material of each of the gate electrode, the source electrode and the drain electrode is one of Mo, Al, Cu, Ti, a molybdenum alloy, an aluminum alloy, a copper alloy, and a titanium alloy; the gate insulation layer includes at least one layer of SiOx and/or one layer of SiNx.

The present invention further provides a P-type thin-film transistor, comprising: an active layer, a gate insulation layer, a gate electrode, a source electrode and a drain electrode; wherein the gate insulation layer is located above the active layer, the gate electrode is located above the gate insulation layer, a projection of the gate electrode on the gate insulation layer is within the gate insulation layer, a projection of the gate insulation layer on the active layer is within the active layer; the active layer includes two doped regions, and the two doped regions are located at two sides of a region located below the gate insulation layer; and the source electrode and the drain electrode are respectively located above the two doped regions, and the source electrode and the drain electrode are respectively connected with the two doped regions.

Preferably, the P-type thin-film transistor further includes an interlayer dielectric layer located above the active layer, the interlayer dielectric layer covers the gate electrode, and the interlayer dielectric layer is provided with two vias; the two vias are respectively located above two doped regions, the source electrode and the drain electrode are respectively connected with the two doped regions through the two vias; a range of a thickness of the interlayer dielectric layer is 2000˜10000 angstrom; the interlayer dielectric layer includes at least one layer of SiOx and/or at least one layer of SiNx.

Preferably, a range of a thickness of the active layer is 100˜1000 angstrom; a material of the active layer is a copper oxide material, and the copper oxide material can be one or at least two of Cu2O, CuAlO2, and LaCuOS; a range of a thickness of each of the source electrode and the drain electrode is 2000˜8000 angstrom; a range of a thickness of the gate insulation layer is 1000˜3000 angstrom; a material of each of the gate electrode, the source electrode and the drain electrode is one of Mo, Al, Cu, Ti, a molybdenum alloy, an aluminum alloy, a copper alloy, and a titanium alloy; the gate insulation layer includes at least one layer of SiOx and/or one layer of SiNx.

The present invention has following beneficial effects: comparing to the conventional P-type thin-film transistor, in the P-type thin-film transistor provided by the present invention, after etching, a length difference is existed between the gate electrode and a gate insulation layer. That is, a projection of the gate electrode on the gate insulation layer has certain of distance with respect to two sides of the gate insulation layer. The doped regions on the active layer are respectively located at two sides of a region below the gate insulation layer. The P-type thin-film transistor provided by the present invention adopts a top gate self-aligned structure, that is, the gate electrode is disposed above the active layer, and an overlapped region is not existed between the gate electrode and the doped regions corresponding to the source electrode and the drain electrode. The present invention can decrease the parasitic capacitance of the P-type thin-film transistor. The length difference between the gate electrode and the gate insulation layer of the P-type thin-film transistor is helpful to decrease a leakage current among the gate electrode, and the source/drain electrode of the P-type thin-film transistor.

### BRIEF DESCRIPTION OF THE DRAWINGS

In order to more clearly illustrate the technical solution in the present invention or in the prior art, the following will illustrate the figures used for describing the embodiments or the prior art. It is obvious that the following figures are only some embodiments of the present invention. For the person of ordinary skill in the art without creative effort, it can also obtain other figures according to these figures.

FIG. 1 is a schematic diagram of forming an active layer according to the present invention;

FIG. 2 is a schematic diagram of forming a gate insulation layer and a gate metal layer according to the present invention;

FIG. 3 is a schematic diagram of forming a photoresist layer according to the present invention;

FIG. 4 is a schematic diagram of patterned photoresist layer and a gate metal layer after being etched according to the present invention;

FIG. 5 is a schematic diagram of the gate insulation layer after being etched, and the active layer after being doped according to the present invention;

FIG. 6 is a schematic diagram of a structure shown in FIG. 5 after removing the photoresist layer according to the present invention;

FIG. 7 is a schematic diagram of forming an interlayer dielectric layer and two vias on the interlayer dielectric layer according to the present invention;

FIG. 8 is a schematic diagram of forming a source electrode and a drain electrode; and

FIG. 9 is a schematic diagram of forming a passivation layer.

### DETAILED DESCRIPTION OF THE PREFERRED EMBODIMENT

The present invention provides a manufacturing method for a P-type thin-film transistor, and the method includes following steps:

As shown in FIG. 1, depositing a buffering layer 2 on a glass substrate 3 and forming an active layer 11 having a P-type material on the buffering, layer 2.

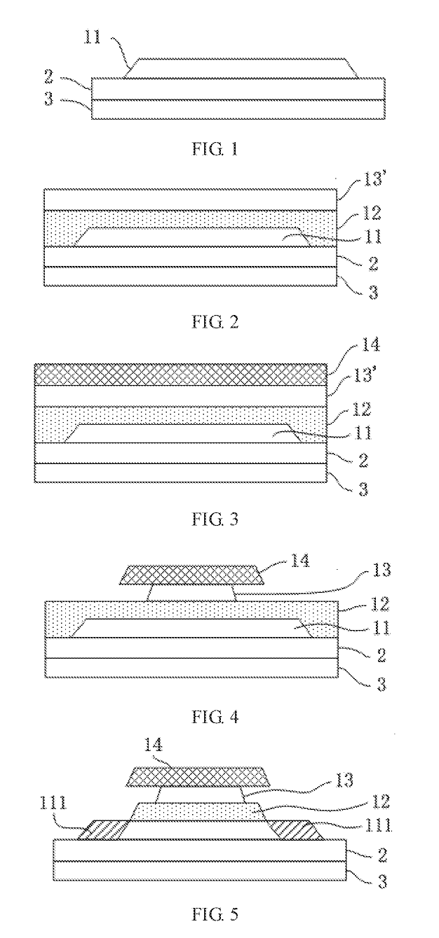

As shown in FIG. 2, forming a gate insulation layer 12 on the active layer 11.

Depositing a gate metal layer 13′ on the gate insulation layer 12.

As shown in FIG. 3, forming a photoresist layer 14 on the gate metal layer 13′, and patterning the photoresist layer 14.

Etching the gate metal layer 13′ in order to form a gate electrode 13 such that a projection of the gate electrode 13 on the patterned photoresist layer 14 is within the patterned photoresist layer 14.

Using the patterned photoresist layer 14 as a barrier layer to perform an etching process to the gate insulation layer 12 such that a projection of the gate electrode 13 on the gate insulation layer 12 is within the gate insulation layer 12. A projection of the gate insulation layer 12 on the active layer 11 is within the active layer 11. That is, using the gate electrode 13 as a self-alignment to continue to etch the gate insulation layer 12, and adjusting an etching time such that after etching, a length of the gate insulation layer 12 is greater than a length of the gate electrode 13 and less than a length of the active layer. After etching the length of the gate insulation 12 is slightly less than the length of the photoresist layer 14.

As shown in FIG. 5, doping two sides of the active layer 11 located below the gate insulation layer 12 after being etched in order to obtain doped regions 111. Specifically, the step of doping two sides of the active layer 11 located below the gate insulation layer 12 after being etched can use the photoresist layer 14 or the gate electrode 13 as a barrier layer such that a region right below the gate insulation layer 12 is not doped.

Forming a source electrode 16 and a drain electrode 17 on the doped regions 111.

Furthermore, the manufacturing method for a P-type thin-film transistor also includes following steps:

Removing the photoresist layer 14 after etching the gate metal layer 13′ to form the gate electrode 13 and before doping the active layer, or removing the photoresist layer 14 after doping the active layer 11.

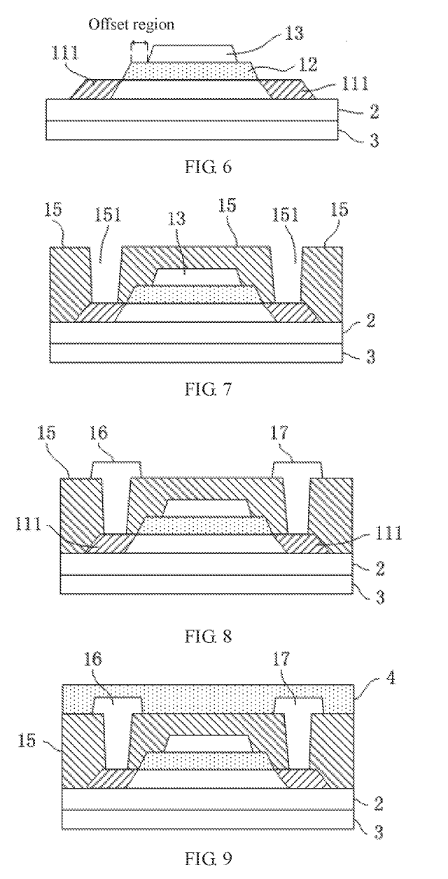

For example, as shown in FIG. 6, removing the photoresist layer 4 after performing the doping process to the active layer 11;

A range of a thickness of the buffering layer 2 is 1000˜5000 angstrom;

The buffering layer 2 includes at least one layer of SiOx and/or at least one layer of SiNx.

Furthermore, the manufacturing method for the P-type transistor further includes following steps:

As shown in FIG. 7, forming an interlayer dielectric layer 15 (that is, an ILD layer) on the buffering layer 2, and the interlayer dielectric layer 15 covers the gate electrode 13;

Forming two vias 151 on the interlayer dielectric layer 15, and the two vias 151 is located above the doped regions 111 of the active layer 11;

Forming a source electrode 16 and a drain electrode 17 on the doped region 111 of the active layer 11. Specifically:

As shown in FIG. 8, forming the source electrode 16 and the drain electrode 17 on the interlayer dielectric layer 15, and the source electrode 16 and the drain electrode 17 are respectively connected with the doped regions 111 of the active layer 11 through the two vias 151.

Furthermore, the manufacturing method for the P-type transistor further includes following steps:

As shown in FIG. 9, forming a passivation layer 4 on the interlayer dielectric layer 15, and the passivation layer 4 covers the source electrode 16 and the drain electrode 17. Wherein, a range of a thickness of the passivation layer 4 is 1000˜5000 angstrom, and the passivation layer 4 includes at least one layer of SiOx and/or at least one layer of SiNx.

Furthermore, a range of a thickness of the interlayer dielectric layer 15 is 2000˜10000 angstrom, and the interlayer dielectric layer 15 includes at least one layer of SiOx and/or at least one layer of SiNx.

Furthermore, using a wet etching method to perform the etching process to the gate metal layer 13′ in order to form the gate electrode 13. Using a dry etching method to etch the gate insulation layer 12, and using a UV light to define a pattern of the photoresist layer 14.

Furthermore, a range of a thickness of the active layer 11 is 100˜1000 angstrom.

The material of the active layer 11 is a copper oxide material. The copper oxide material can be one or at least two of Cu2O, CuAlO2 and LaCuOS. Wherein, Cu represents copper element, Al represents aluminum element, S represents sulfur element, La represents lanthanum element, O represents oxygen element. When manufacturing the active layer 11, coating a copper oxide material on the buffering layer 2, defining an active region of the copper oxide material, that is, performing a patterning process to the copper oxide material such that the active layer 11 after patterning is located at a preset region such as locating at an effective display region of the display panel.

A range of a thickness of the source electrode 16 and the drain electrode 17 is 2000˜8000 angstrom. A range of a thickness of the gate insulation layer 12 is 1000˜3000 angstrom. A material of each of the gate electrode 13, the source electrode 16 and the drain electrode 17 is one of Mo (molybdenum), Al (aluminum), Cu (copper), Ti (titanium), molybdenum alloys, aluminum alloys, copper alloys, and titanium alloys. The gate insulation layer 12 includes at least one layer of SiOx and/or one layer of SiNx.

The present invention further provides with a P-type thin-film transistor, the P-type thin-film transistor includes: an active layer 11, a gate insulation layer 2, a gate electrode 13, a source electrode 16 and a drain electrode 17.

The gate insulation layer 12 is located above the active layer 11, the gate electrode 13 is located above the gate insulation layer 12, a projection of the gate electrode 13 on the gate insulation layer 12 is within the gate insulation layer 12, a projection of the gate insulation layer 12 on the active layer 11 is within the active layer 11

The active layer 11 includes two doped regions 111, and the two doped regions 111 are located at two sides of a region located below the gate insulation layer 12. The doped regions are treated with a doping process.

The source electrode 16 and the drain electrode 17 are respectively located above the two doped regions 111, and the source electrode 16 and the drain electrode 17 are respectively connected with the two doped regions 111.

Furthermore, the P-type thin-film transistor further includes an interlayer dielectric layer 15 located above the active layer 11, the interlayer dielectric layer 15 covers the gate electrode 13, and the interlayer dielectric layer 15 is provided with two vias 151. The two vias 151 are respectively located above two doped regions 111, the source electrode 16 and the drain electrode 17 are respectively connected with the two doped regions 111 through the two vias 151.

A range of a thickness of the interlayer dielectric layer 15 is 2000˜10000 angstrom, and the interlayer dielectric layer 15 includes at least one layer of SiOx and/or at least one layer of SiNx.

Furthermore, a range of a thickness of the active layer 11 is 100˜1000 angstrom, the material of the active layer 11 is a copper oxide material. The copper oxide material can be one or at least two of Cu2O, CuAlO2, LaCuOS.

A range of a thickness of the source electrode 16 and the drain electrode 17 is 2000˜8000 angstrom. A range of a thickness of the gate insulation layer 12 is 1000˜3000 angstrom. A material of each gate electrode 13, source electrode 16 and drain electrode 17 is one of Mo (molybdenum), Al (aluminum), Cu (copper), Ti (titanium), a molybdenum alloy, an aluminum alloy, a copper alloy, and a titanium alloy. The gate insulation layer 12 includes at least one layer of SiOx and/or one layer of SiNx.

In summary, comparing to the conventional P-type thin-film transistor, in the P-type thin-film transistor provided by the present invention, after etching, a length difference is existed between the gate electrode 13 and a gate insulation layer 12. That is, a projection of the gate electrode 13 on the gate insulation layer 12 has a certain of distance with respect to two sides of the gate insulation layer 12. The doped regions 111 on the active layer 11 are respectively located at two sides of a region below the gate insulation layer 12. A offset region (GI offset) on the gate insulation layer as shown in FIG. 6 is existed. An electric field among the gate electrode 13, the source electrode 16 and the drain electrode 17 does not have function in the offset region. The P-type thin-film transistor provided by the present invention adopts a top gate self-aligned structure, that is, the gate electrode 13 is disposed above the active layer 11, and an overlapped region is not existed between the gate electrode 13 and the doped regions 111 corresponding to the source electrode 16 and the drain electrode 17. The present invention can decrease the parasitic capacitance of the P-type thin-film transistor. The length difference between the gate electrode 13 and the gate insulation layer 12 of the P-type thin-film transistor is helpful to decrease a leakage current among the gate electrode 13, and the source 16/drain 17 electrode of the P-type thin-film transistor.

The P-type thin-film transistor of the present invention can be applied in an AMOLED driving backplane, and can cooperate with an N-type transistor to realize a logic circuit.

The above is only the specific implementation mode of the present disclosure and not intended to limit the scope of protection of the present disclosure, and any variations or replacements apparent to those skilled in the art within the technical scope of the present disclosure shall fall within the scope of protection of the present disclosure. Therefore, the scope of protection of the present disclosure should be the scope of protection of the claims.

What is claimed is:

1. A manufacturing method for P-type transistor, comprising steps of:
forming an active layer having a P-type material on a buffering layer;
forming a gate insulation layer on the active layer;
depositing a gate metal layer on the gate insulation layer;
forming a photoresist layer on the gate metal layer, and patterning the photoresist layer;
etching the gate metal layer in order to form a gate electrode such that a projection of the gate electrode on the patterned phoresist layer is within the patterned photoresist layer;
using the patterned photoresist layer as a barrier layer to etch the gate insulation layer such that a projection of the gate electrode on the gate insulation layer is within the gate insulation layer, and a projection of the gate insulation layer on the active layer is within the active layer;
doping two side regions of the active layer located below e gate insulation layer after being etched; and
forming a source electrode and a drain electrode on the doped regions of the active layer.

2. The manufacturing method for P-type thin-film transistor according to claim 1, wherein the method further comprises steps of:
forming an interlayer dielectric layer on the buffering layer, and the interlayer dielectric layer covers the gate electrode;
forming two vias on the interlayer dielectric layer, and the two vias are located above the doped regions of the active layer;
forming the source electrode and the drain electrode on the doped regions of the active layer, wherein forming the source electrode and the drain electrode on the interlayer dielectric layer, and the source electrode and the drain electrode are respectively connected with the doped regions of the active layer through the two vias.

3. The manufacturing method for P-type thin-film transistor according to claim 2, wherein the method further comprises steps of:
forming a passivation layer on the interlayer dielectric layer, and the passivation layer covers the source electrode and the drain electrode, wherein a range of a thickness of the passivation layer is 1000˜5000 angstrom, and the passivation layer includes at least one layer of SiOx and/or at least one layer of SiNx.

4. The manufacturing method for P-type thin-film transistor according to claim 2, wherein a range of a thickness of the interlayer dielectric layer is 2000˜10000 angstrom, and the interlayer dielectric layer includes at least one layer of SiOx and/or at least one layer of SiNx.

5. The manufacturing method for P-type thin-film transistor according to claim 1, wherein the method further includes steps of:
forming the buffering layer on a glass substrate;
removing the photoresist layer after etching the gate metal layer to form the gate electrode and before doping the active layer, or removing the photoresist layer after doping the active layer;
a range of a thickness of the buffering layer is 1000˜5000 angstrom;
the buffering layer includes at least one layer of SiOx and/or at least one layer of SiNx.

6. The manufacturing method for P-type thin-film transistor according to claim 1, wherein the method uses a wet etching method to etch the gate metal layer in order to form the gate electrode, and uses a dry etching method to etch the gate insulation layer, and uses a UV light to define a pattern of the photoresist layer.

7. The manufacturing method for P-type thin-film transistor according to claim 1, wherein
a range of a thickness of the active layer is 100˜1000 angstrom;
a material of the active layer is a copper oxide material, and the copper oxide material is one or at least two of Cu2O, CuAlO2, LaCuOS;
a range of a thickness of each of the source electrode and the drain electrode is 2000˜8000 angstrom;
a range of a thickness of the gate insulation layer is 1000˜3000 angstrom;
a material of each of the gate electrode, the source electrode and the drain electrode is one of Mo, Al, Cu, Ti, a molybdenum alloy, an aluminum alloy a copper alloy, and a titanium alloy;
the gate insulation layer includes at least one layer of SiOx and/or one layer of SiNx.

8. A manufacturing method for P-type thin-film transistor, comprising steps of:
forming an active layer having a P-type material on a buffering layer;
forming a gate insulation layer on the active layer;
depositing a gate metal layer on the gate insulation layer;
forming a photoresist layer on the gate metal layer, and patterning the photoresist layer;
etching the gate metal layer in order to form a gate electrode such that a projection of the gate electrode on the patterned photoresist layer is within the patterned photoresist layer;
using the patterned photoresist layer as a barrier layer to etch the gate insulation layer such that a projection of the gate electrode on the gate insulation layer is within the gate insulation layer, and a projection of the gate insulation layer on the active layer is within the active layer;
doping two side regions of the active layer located below the gate insulation layer after being etched;
forming a source electrode and a drain electrode on the doped regions of the active layer;
wherein the method for P-type thin-film transistor further includes steps of:
forming the buffering layer on a glass substrate;
removing the photoresist layer after etching the gate metal layer to form the gate electrode and before doping the active layer, or removing the photoresist layer after doping the active layer;
a range of a thickness of the buffering layer is 1000˜5000 angstrom;
the buffering layer includes at least one layer of SiOx and/or at least one layer of SiNx.

9. The manufacturing method for P-type thin-film transistor according to claim 8, wherein the method further comprises steps of:
forming an interlayer dielectric layer on the buffering layer, and the interlayer dielectric layer covers the gate electrode;
forming two vias on the interlayer dielectric layer, and the two vias are located above the doped regions of the active layer;
forming the source electrode and the drain electrode on the doped regions of the active layer, wherein forming the source electrode and the drain electrode on the interlayer dielectric layer, and the source electrode and the drain electrode are respectively connected with the doped regions of the active layer through the two vias.

10. The manufacturing method for P-type thin-film transistor according to claim 9, wherein the method further comprises steps of:
forming a passivation layer on the interlayer dielectric layer, and the passivation layer covers the source electrode and the drain electrode, wherein a range of a thickness of the passivation layer is 1000˜5000 angstrom, and the passivation layer includes at least one layer of SiOx and/or at least one layer of SiNx.

11. The manufacturing method for P-type thin-film transistor according to claim 9, wherein a range of a thickness of the interlayer dielectric layer is 2000˜10000 angstrom, and the interlayer dielectric layer includes at least one layer of SiOx and/or at least one layer of SiNx.

12. The manufacturing method for P-type thin-film transistor according to claim 8, wherein the method uses a wet etching method to etch the gate metal layer in order to form the gate electrode, and uses a dry etching method to etch the gate insulation layer, and uses a yellow light to define a pattern of the photoresist layer.

13. The manufacturing method for P-type thin-film transistor according to claim 8, wherein
a range of a thickness of the active layer is 100˜1000 angstrom;
a material of the active layer is a copper oxide material, and the copper oxide material is one or at least two of Cu2O, CuAlO2, LaCuOS;
a range of a thickness of each of the source electrode and the drain electrode is 2000˜8000 angstrom;
a range of a thickness of the gate insulation layer is 1000˜3000 angstrom;
a material of each of the gate electrode, the source electrode and the drain electrode is one of Mo, Al, Cu, Ti, a molybdenum alloy, an aluminum alloy, a copper alloy, and a titanium alloy;
the gate insulation layer includes at least one layer of SiOx and/or one layer of SiNx.

14. A P-type thin-film transistor, comprising:
an active layer, a gate insulation layer, a gate electrode, a source electrode and a drain electrode;
wherein the gate insulation layer is located above the active layer, the gate electrode is located above the gate insulation layer, a projection of the gate electrode on the gate insulation layer is within the gate insulation layer, a projection of the gate insulation layer on the active layer is within the active layer;
the active layer includes two doped regions, and the two doped regions are located at two sides of a region located below the gate insulation layer; and
the source electrode and the drain electrode are respectively located above the two doped regions, and the source electrode and the drain electrode are respectively connected with the two doped regions.

15. The P-type thin-film transistor according to claim 14, wherein the P-type thin-film transistor further includes an interlayer dielectric layer located above the active layer, the interlayer dielectric layer covers the gate electrode, and the interlayer dielectric layer is provided with two vias; the two vias are respectively located above two doped regions, the source electrode and the drain electrode are respectively connected with the two doped regions through the two vias;
a range of a thickness of the interlayer dielectric layer is 2000˜10000 angstrom;
the interlayer dielectric layer includes at least one layer of SiOx and/or at least one layer of SiNx.

16. The P-type thin-film transistor according to claim 14, wherein
a range of a thickness of the active layer is 100˜1000 angstrom;
a material of the active layer is a copper oxide material, and the copper oxide material can be one or at least two of Cu2O, CuAlO2, and LaCuOS;
a range of a thickness of each of the source electrode and the drain electrode is 2000˜8000 angstrom;
a range of a thickness of the gate insulation layer is 1000—3000 angstrom;
a material of each of the gate electrode, the source electrode and the drain electrode is one of Mo, Al, Cu, Ti, a molybdenum alloy, an aluminum alloy, a copper alloy, and a titanium alloy;
the gate insulation layer includes at least one layer of SiOx and/or one layer of SiNx.
